(19) United States
(12) Patent Application Publication
(10) Pub. No.: US 2026/0142637 A1
(43) Pub. Date: May 21, 2026

(54) FILTER CIRCUIT AND COMMUNICATION DEVICE

(71) Applicant: Kabushiki Kaisha Toshiba, Tokyo (JP)

(72) Inventor: Tamio KAWAGUCHI, Yokohama Kanagawa (JP)

(21) Appl. No.: 19/248,908

(22) Filed: Jun. 25, 2025

(30) Foreign Application Priority Data
Nov. 18, 2024 (JP) 2024-200921

(51) Int. Cl. H03H 7/01; H04B 1/40

(52) U.S. Cl. CPC H03H 7/0115; H04B 1/40

(57) ABSTRACT

According to one embodiment, a filter circuit includes first and second terminals, and a filter element. The filter element includes a transmission line coupled with the first and second terminals, and first and second resonant elements coupled with the transmission line. The first and second resonant elements resonate at a frequency in a first band being of an object. The first resonant element is coupled to a position between the input portion and the intermediate portion. The second resonant element is coupled to a position between the intermediate portion and the output portion. The intermediate portion includes first to third portions. A line width of the second portion is different from a line width of the first portion and a line width of the third portion.

### CROSS-REFERENCE TO RELATED APPLICATIONS

This application is based upon and claims the benefit of priority from Japanese Patent Application No. 2024-200921, filed on Nov. 18, 2024; the entire contents of which are incorporated herein by reference.

### FIELD

Embodiments described herein relate generally to a filter circuit and a communication device.

### BACKGROUND

For example, filter circuits are used in high-frequency circuits, and there is a demand for improved characteristics of the filter circuits.

### BRIEF DESCRIPTION OF THE DRAWINGS

FIGS. 1A and 1B are schematic diagrams illustrating a filter circuit according to a first embodiment;

FIG. 2 is a graph illustrating the characteristics of the filter circuit according to the first embodiment;

FIG. 3 is a schematic diagram illustrating a filter circuit of a reference example;

FIG. 4 is a graph illustrating the characteristics of the filter circuit of the reference example;

FIGS. 5A and 5B are schematic diagrams illustrating resonant elements;

FIG. 6 is a graph illustrating the characteristics of the filter circuit of the reference example;

FIG. 7 is a graph illustrating the characteristics of the filter circuit of the reference example;

FIG. 8 is a graph illustrating the characteristics of the filter circuit according to the first embodiment;

FIG. 9 is a schematic diagram illustrating a filter circuit according to the first embodiment;

FIGS. 10A and 10B are schematic views illustrating a filter circuit according to the first embodiment;

FIGS. 11A and 11B are schematic views illustrating a filter circuit according to the first embodiment;

FIGS. 12A and 12B are schematic views illustrating a filter circuit according to the first embodiment;

FIGS. 13A and 13B are schematic views illustrating a filter circuit according to the first embodiment;

FIGS. 14A and 14B are schematic views illustrating a filter circuit according to the first embodiment;

FIGS. 15A and 15B are schematic diagrams illustrating a filter circuit according to the first embodiment;

FIG. 16 is a schematic cross-sectional view illustrating a filter circuit according to the first embodiment;

FIGS. 17A and 17B are schematic diagrams illustrating a filter circuit according to the first embodiment; and

FIG. 18 is a schematic diagram illustrating a communication device according to a second embodiment.

### DETAILED DESCRIPTION

According to one embodiment, a filter circuit includes a first terminal, a second terminal, and a filter element. The filter element includes a transmission line configured to be coupled with the first terminal and the second terminal, and a first resonant element and a second resonant element configured to be coupled with the transmission line. The first resonant element and the second resonant element are configured to resonate at a frequency in a first band being of an object. The transmission line includes an input portion configured to be coupled with the first terminal, an output portion configured to be coupled with the second terminal, and an intermediate portion between the input portion and output portion. The first resonant element is configured to be coupled to a first position between the input portion and the intermediate portion. The second resonant element is configured to be coupled to a second position between the intermediate portion and the output portion. The intermediate portion includes a first portion, a second portion between the first portion and the output portion, and a third portion between the second portion and the output portion. A second line width of the second portion is different from a first line width of the first portion. The second line width is different from a third line width of the third portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

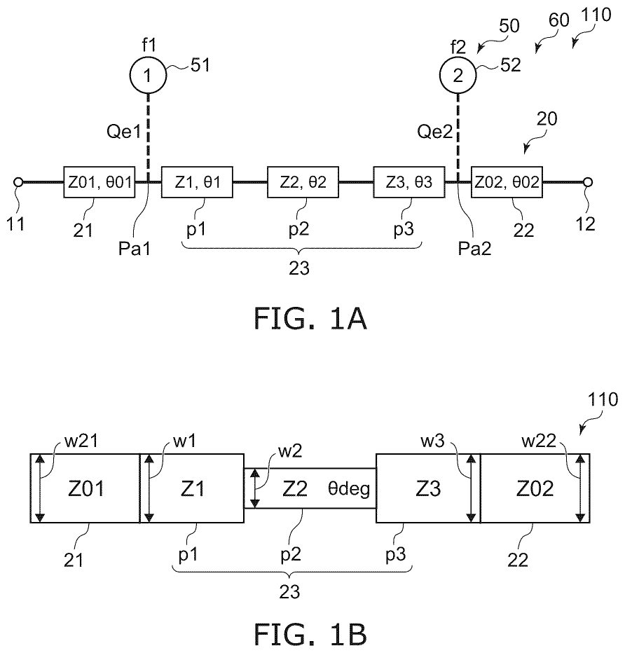

FIGS. 1A and 1B are schematic diagrams illustrating a filter circuit according to a first embodiment.

As shown in FIG. 1A, a filter circuit 110 according to the embodiment includes a first terminal 11, a second terminal 12, and a filter element 60. For example, a signal is input to the first terminal 11. The first terminal 11 is configured to receive the input signal. The second terminal 12 is configured to output a signal. For example, the first terminal 11 is an input terminal. The second terminal 12 is an output terminal.

The filter element 60 includes a transmission line 20 and a plurality of resonant elements 50. The transmission line 20 is configured to be coupled with the first terminal 11 and the second terminal 12. The plurality of resonant elements 50 are configured to be coupled with the transmission line 20.

The plurality of resonant elements 50 resonate at a frequency of a first band being of an object. The first band corresponds, for example, to an attenuation band. The first band may correspond, for example, to a stop band. At least a part of the band except for the first band corresponds to a pass band. The filter circuit 110 is, for example, a band stop filter.

For example, the plurality of resonant elements 50 include a first resonant element 51 and a second resonant element 52. The second resonant element 52 may be, for example, next to the first resonant element 51.

The transmission line 20 includes an input portion 21, an output portion 22, and an intermediate portion 23. The input portion 21 is configured to be coupled with the first terminal 11. The output portion 22 is configured to be coupled with the second terminal 12. The intermediate portion 23 is between the input portion 21 and the output portion 22.

The first resonant element 51 is configured to be coupled to a first position Pa1 between the input portion 21 and the intermediate portion 23. The second resonant element 52 is configured to be coupled to a second position Pa2 between the intermediate portion 23 and the output portion 22. For example, no other resonant element is coupled between the first position Pa1 and the second position Pa2.

The intermediate portion 23 includes a first portion p1, a second portion p2, and a third portion p3. The second portion p2 is between the first portion p1 and the output portion 22. The third portion p3 is between the second portion p2 and the output portion 22. The first portion p1 is connected to the input portion 21. The third portion p3 is connected to the output portion 22.

As shown in FIG. 1B, a second line width w2 of the second portion p2 is different from a first line width w1 of the first portion p1. The second line width w2 is different from a third line width w3 of the third portion p3. For example, the second line width w2 is narrower than the first line width w1. For example, the second line width w2 is narrower than the third line width w3.

The difference in width causes a difference in the characteristic impedance. For example, a second characteristic impedance Z2 of the second portion p2 is different from a first characteristic impedance Z1 of the first portion p1. The second characteristic impedance Z2 is different from a third characteristic impedance Z3 of the third portion p3. The characteristic impedance changes discontinuously. At the position where the width (i.e., the characteristic impedance) changes discontinuously, a part of the signal is reflected.

For example, a part of the signal input to the first terminal 11 is reflected, for example, at the boundary between the second portion p2 and the third portion p3. The phase of the reflected wave is, for example, opposite to the phase of the reflected waves from the first resonant element 51 and the second resonant element 52 at a certain frequency. It is considered that these reflected waves act to attenuate each other. This results in good reflection characteristics in the passband. For example, good pass characteristics can be obtained even in the high frequency band of the first band (attenuation band). This results in good pass characteristics over a wide band. According to the embodiment, a filter circuit with improved characteristics can be provided.

As shown in FIG. 1A, in this example, the first terminal 11 is connected to the input portion 21. The input portion 21 is connected to the first portion p1. The first portion p1 is connected to the second portion p2. The second portion p2 is connected to the third portion p3. The third portion p3 is connected to the output portion 22. The output portion 22 is connected to the second terminal 12.

The input portion 21 has an input portion characteristic impedance Z01 at a frequency in the first band, and an input portion electrical length θ01 at the frequency in the first band. The first portion p1 has a first characteristic impedance Z1 at the frequency in the first band, and a first electrical length θ1 at the frequency in the first band. The second portion p2 has a second characteristic impedance Z2 at the frequency in the first band, and a second electrical length θ2 at the frequency in the first band. The third portion p3 has a third characteristic impedance Z3 at the frequency in the first band, and a third electrical length θ3 at the frequency in the first band. The output portion 22 has an output portion characteristic impedance Z02 at the frequency in the first band, and an output portion electrical length θ02 at the frequency in the first band.

In the example of FIG. 1B, the second characteristic impedance Z2 of the second portion p2 is higher than the first characteristic impedance Z1 of the first portion p1. The second characteristic impedance Z2 is higher than the third characteristic impedance Z3 of the third portion p3.

As shown in FIG. 1B, a line width of the input portion 21 is defined as an input portion line width w21. A line width of the output portion 22 is defined as an output portion line width w22. In this example, the second line width w2 is narrower than the input portion line width w21. The second line width w2 is narrower than the output portion line width w22.

In this example, the second characteristic impedance Z2 is higher than the input portion characteristic impedance Z01 of the input portion 21. The second characteristic impedance Z2 is higher than the output portion characteristic impedance Z02 of the output portion 22.

As will be described later, the relative relationship of the line widths may be the opposite of that described above. The relative relationship of the characteristic impedances may be the opposite of that described above.

The first resonant element 51 is configured to resonate at a first resonant frequency f1. The first resonant element 51 is coupled to the first position Pa1 with a first coupling strength, which is defined by the external-Q factor Qe1. The second resonant element 52 is configured to resonate at a second resonant frequency f2. The second resonant element 52 is coupled to the second position Pa2 with a second coupling strength, which is defined by the external-Q factor Qe2.

The coupling is represented by an external Q value Qe. The coupling includes, for example, coupling by an electromagnetic field. The coupling may include, for example, coupling using a capacitance. The coupling may include, for example, coupling using an inductor. The coupling may include, for example, coupling using a ¼ wavelength impedance transformer.

The first resonant frequency f1 is a frequency in the first band. The second resonant frequency f2 is a frequency in the first band. The second resonant frequency f2 may be the same as the first resonant frequency f1. The second resonant frequency f2 may be different from the first resonant frequency f1.

In the embodiment, the input portion characteristic impedance Z01 of the input portion 21 may be substantially 50 Ω. The output portion characteristic impedance Z02 of the output portion 22 may be substantially 50 Ω. In general, the characteristic impedance of an external circuit is often set to 50 Ω. By matching the above characteristic impedance with the external circuit, good matching can be obtained with the external circuit.

In one example, the first characteristic impedance Z1 of the first portion p1 may be substantially 50 Ω, for example. The third characteristic impedance Z3 of the third portion p3 may be substantially 50 Ω, for example.

The electrical length between the first position Pa1 and the second position Pa2 corresponds to the electrical length of the intermediate portion 23 (intermediate portion electrical length). The intermediate portion electrical length may be, for example, 90×(2n+1) degrees. “n” is an integer equal to or greater than 0. The intermediate portion electrical length may be substantially 90 degrees.

In this example, the intermediate portion electrical length corresponds to the sum of the first electrical length θ1 of the first portion p1, the second electrical length θ2 of the second portion p2, and the third electrical length θ3 of the third portion p3. The sum electrical length is set to, for example, 90×(2n+1) degrees in the first frequency band. In a case where the sum electrical length is 90×(2n+1) degrees, the characteristics of the first resonant element 51 and the second resonant element 52 are combined. For example, in a case wherein the first resonance frequency f1 of the first resonant element 51 is the same as the second resonance frequency f2 of the second resonant element 52, the attenuation level becomes maximum at the first resonance frequency f1.

On the other hand, in a case where the electrical length is different from 90×(2n+1) degrees, the attenuation level decreases. It is preferable that the absolute value of the difference between the electrical length and 90×(2n+1) degrees is 0.2 times or less than 90×(2n+1) degrees. Thereby, a practical large the attenuation level can be obtained.

In the filter circuit 110, a component of a part of the signal input to the first terminal 11 has a resonant frequency of the first resonant element 51 and the second resonant element 52. This component is reflected by the first resonant element 51 and the second resonant element 52. For example, the signal reflected by the first resonant element 51 and the second resonant element 52 and the signal reflected at the boundary between the second portion p2 and the third portion p3 act to cancel each other out. This provides good filter characteristics. In the embodiment, good filter characteristics are provided by utilizing the reflected waves based on the plurality of resonant elements 50 and the reflected waves at the discontinuous boundary provided in the transmission line 20.

In the embodiment, signals in a frequency band away from the resonant frequencies of the plurality of resonant elements 50 are output to the second terminal 12 without being substantially affected by the plurality of resonant elements 50. This provides a filter circuit that reflects a specific band.

In the embodiment, the second electrical length θ2 of the second portion p2 may be not less than 40 degrees and not more than 50 degrees at the frequency in the first band. For example, the second electrical length θ2 of the second portion p2 may be substantially 45 degrees. The first electrical length θ1 of the first portion p1 may be substantially 22.5 degrees. The third electrical length θ3 of the third portion p3 may be substantially 22.5 degrees.

In a filter circuit of a reference example being general, the characteristic impedance of the transmission line connected to the first terminal 11 and the characteristic impedance of the transmission line connected to the second terminal 12 are set to 50 Ω. This provides good matching between the filter circuit and the external circuit to which it is connected.

In the embodiment, the input portion characteristic impedance Z01 of the input portion 21 and the output portion characteristic impedance Z02 of the output portion 22 may be set arbitrarily.

As described above, in the embodiment, the discontinuous structure is provided in the intermediate portion 23 of the transmission line 20. For example, a ratio of an absolute value of a difference between the second characteristic impedance Z2 and the first characteristic impedance Z1 to the first characteristic impedance Z1 may be, for example, 0.01 or more. For example, a ratio of an absolute value of a difference between the second characteristic impedance Z2 and the third characteristic impedance Z3 to the third characteristic impedance Z3 may be, for example, 0.01 or more. The reflected wave is obtained by the discontinuous structure.

For example, an absolute value of a difference between the second line width w2 and the first line width w1 to the first line width w1 may be, for example, 0.01 or more. For example, an absolute value of a difference between the second line width w2 and the third line width w3 to the third line width w3 may be, for example, 0.01 or more. The reflected wave is obtained by the discontinuous structure.

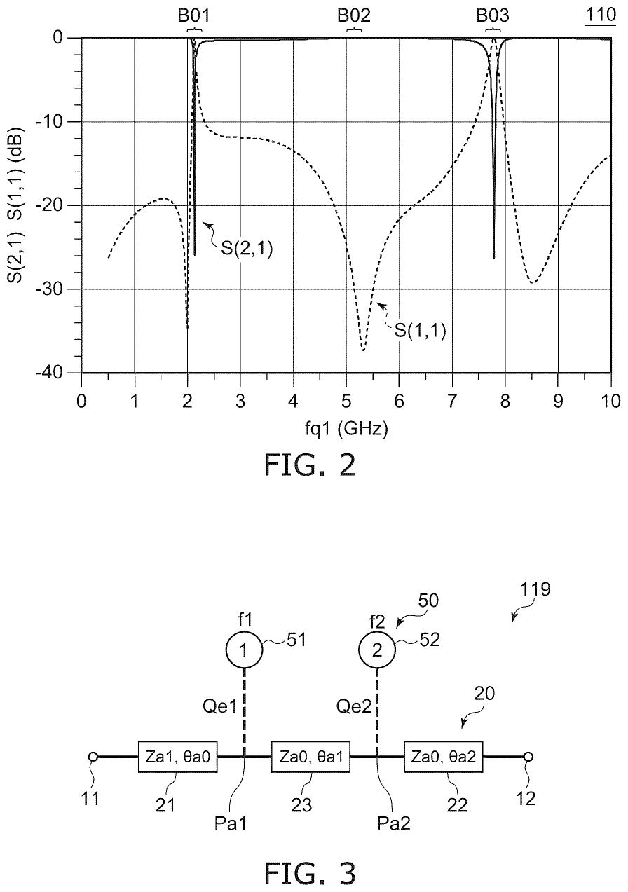

FIG. 2 is a graph illustrating the characteristics of the filter circuit according to the first embodiment.

FIG. 2 illustrates the results of a simulation of the characteristics of the filter circuit 110. In the filter circuit 110, the second line width w2 is different from the first line width w1 and different from the third line width w3. In this example, the second characteristic impedance Z2 is 1.2 times the first characteristic impedance Z1 and 1.2 times the third characteristic impedance Z3. The horizontal axis of FIG. 2 is the frequency fq1. The vertical axis is the transmission characteristic S(2,1) or the reflection characteristic S(1,1). In this example, the first band B01 is about 2 GHz. As already explained, the first band B01 corresponds to the attenuation band (or stop band).

As shown in FIG. 2, in the first band B01, the transmission characteristic S(2,1) is locally low. Good attenuation characteristics are obtained in the first band B01. Furthermore, in the second band B02, which is twice the frequency of the first band B01, the transmission characteristic S(2,1) is high and the reflection characteristic S(1,1) is low. Good transmission characteristic S(2,1) is obtained at the frequency twice that of the first band B01. It is possible to utilize the signal in the second band B02, which is the second harmonic (twice the frequency) of the first band B01, while attenuating the target signal in the first band B01.

As shown in FIG. 2, in this example, the transmission characteristic S(2,1) is locally low in the third band B03, which is a higher frequency band than the first band B01. In the band between the first band B01 and the third band B03, a very high transmission characteristic S(2,1) is obtained. Signals in this range can be effectively used.

In the filter circuit 110, the point at which reflection becomes zero can be adjusted by changing the characteristics of the second portion p2 (at least one of the second characteristic impedance Z2 and the second electrical length θ2).

For example, when the second characteristic impedance Z2 is high, the amount of reflected wave increases. When the level of the reflected wave to be canceled is high, the amount of cancellation can be increased. On the other hand, when the amount of reflected wave becomes too high compared to the level of the reflected wave to be canceled, the reflected wave due to mismatch becomes dominant, and the characteristics deteriorate. The amount of reflected wave can be set to an appropriate amount.

When the second electrical length θ2 is long, the frequency to be canceled shifts to the lower frequency side. When the second electrical length θ2 is short, the frequency to be canceled shifts to the higher frequency side.

In the embodiment, the length of the discontinuous portion (the region in which the characteristic impedance of the first portion p1 and the third portion p3 differs) between the first portion p1 and the third portion p3 may be short. For example, the length of the discontinuous portion may be ⅛ of the wavelength or less. There is substantially no effect of the reflected wave in the first band B01.

Thus, in the filter circuit 110, a line with a different characteristic impedance is provided in the intermediate portion 23 between the first resonant element 51 and the second resonant element 52. This makes it possible to reduce reflected waves of a specific frequency. A filter circuit with good characteristics is obtained.

The intermediate portion electrical length (sum electrical length) of the intermediate portion 23 may be not less than 85 degrees and not more than 95 degrees at frequencies between the fundamental frequency of the fundamental resonance of the first resonant element 51 and the secondary resonance frequency of the secondary resonance of the first resonant element 51. The intermediate portion electrical length (sum electrical length) of the intermediate portion 23 may be not less than 85 degrees and not more than 95 at frequencies between the fundamental frequency of the fundamental resonance of the second resonant element 52 and the secondary resonance frequency of the secondary resonance of the second resonant element 52. For example, good attenuation characteristics are obtained in the first band B01 and the third band B03.

The filter circuit of a reference example will be described below.

FIG. 3 is a schematic diagram illustrating the filter circuit of the reference example.

As shown in FIG. 3, in a filter circuit 119, the transmission line 20 includes the input portion 21, the intermediate portion 23, and the output portion 22. In the filter circuit 119 as well, the first resonant element 51 is coupled to the first position Pa1 between the input portion 21 and the intermediate portion 23. The second resonant element 52 is coupled to the second position Pa2 between the intermediate portion 23 and the output portion 22.

In the filter circuit 119, the characteristic impedance Za0 in the intermediate portion 23 is constant. The discontinuous structure described with respect to the filter circuit 110 is not provided. Therefore, the effect of utilizing the reflection based on the discontinuous structure cannot be obtained.

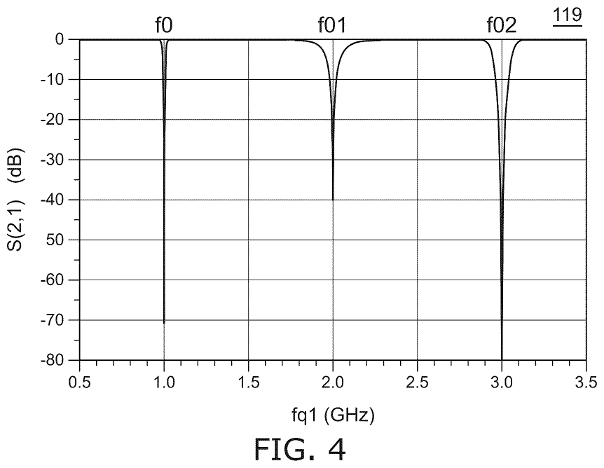

FIG. 4 is a graph illustrating the characteristics of the filter circuit of the reference example.

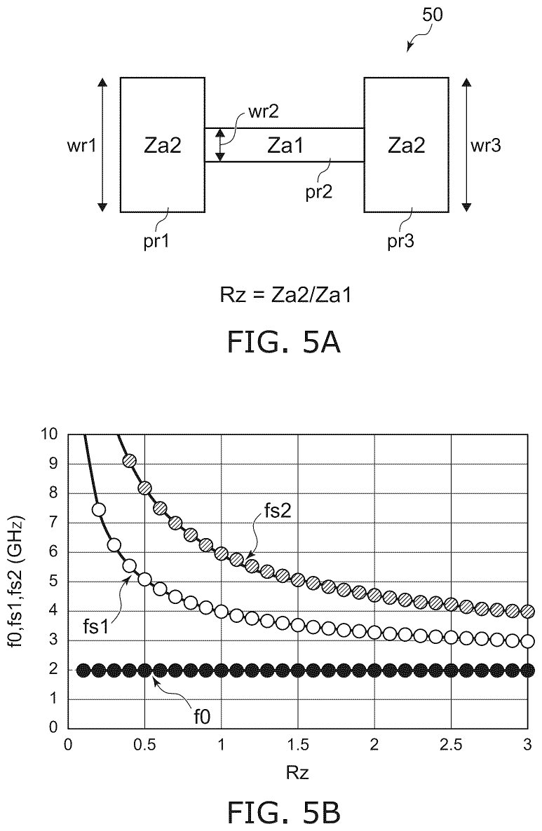

The graph illustrates the transmission characteristics of the filter circuit 119 of the reference example. The horizontal axis is frequency. The vertical axis is the transmission characteristic S(2,1). In the example of FIG. 5, one ½ wavelength resonator is applied as the resonant element 50. This resonant element 50 resonates at ½ wavelength at frequency f0. The resonant element 50 resonates at frequency f01, which is two times frequency f0, and at frequency f02, which is three times frequency f0. In the example of FIG. 4, the transmission characteristic S(2,1) is low at the two times frequency f01. Therefore, a signal of frequency f01 cannot be used. In the reference example, the pass band is narrow.

In such a filter circuit 119 of the reference example, an attempt to improve the characteristics can be considered by applying stepped impedance resonators (SIRs) as described below as the plurality of resonant elements 50.

FIGS. 5A and 5B are schematic diagrams illustrating resonant elements.

As shown in FIG. 5A, an SIR structure is applied to the microstrip lines of the plurality of resonant elements 50. In the SIR structure, the line includes a first region pr1, a second region pr2, and a third region pr3. The second region pr2 is provided between the first region pr1 and the third region pr3. In this example, the first region pr1 and the third region pr3 have a characteristic impedance Za2. The second region pr2 has a characteristic impedance Za1. The characteristic impedance Za1 is different from the characteristic impedance Za2. A ratio of the characteristic impedance Za2 to the characteristic impedance Za1 (i.e., Za2/Za1) is defined as an impedance ratio Rz. The width wr2 of the second region pr2 is narrower than the width wr1 of the first region pr1. The width wr2 of the second region pr2 is narrower than the width wr3 of the third region pr3. By controlling the width, the characteristic impedance can be controlled.

FIG. 5B illustrates a result of a simulation of the characteristics of the line in FIG. 5A. The horizontal axis of FIG. 5(b) is the impedance ratio Rz. The vertical axis is frequency. Frequency f0 is the resonant frequency of the ½ wavelength resonance. Frequency fs1 is the second-order resonant frequency. Frequency fs2 is the third-order resonant frequency.

As shown in FIG. 5B, in a case where the impedance ratio Rz is 1, a higher-order resonance is obtained at a frequency fs1 that is two times the ½ wavelength, and the frequency fs2 that is three times the ½ wavelength. On the other hand, in a case where the impedance ratio Rz is less than 1, the frequency fs1 and the frequency fs2 shift to the higher frequency side. The impedance ratio Rz of less than 1, the passband on the higher frequency side of frequency f01 can become wider. For example, by making the impedance ratio Rz lower than 1, the passband can be made wider.

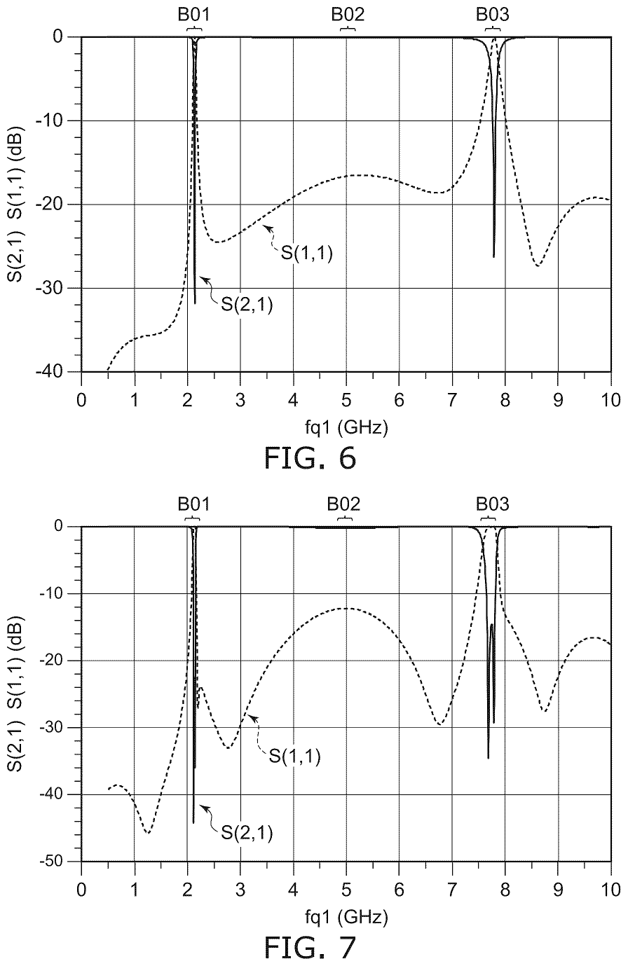

FIGS. 6 and 7 are graphs illustrating the characteristics of the filter circuit of the reference example.

FIG. 6 illustrates a result of a simulation of the characteristics when the SIR structure is applied to the filter circuit 119 of the reference example. In the example of FIG. 6, the SIR structure is applied to two resonant elements 50 (first resonant element 51 and second resonant element 52). The horizontal axis is frequency fq1. The vertical axis is the transmission characteristic S(2,1) or the reflection characteristic S(1,1).

As shown in FIG. 6, in a case where the stepped impedance resonator is applied, a relatively high transmission characteristic S(2,1) is obtained in the second band B02. However, the reflection characteristic S(1,1) is not sufficiently low.

FIG. 7 illustrates a result of a simulation of the characteristics when the SIR structure is applied to the filter circuit 119 of the reference example. In the example of FIG. 7, the SIR structure is applied to three resonant elements 50. The horizontal axis is the frequency fq1. The vertical axis is the transmission characteristic S(2,1) or the reflection characteristic S(1,1).

As shown in FIG. 7, by increasing the number of resonant elements 50 to three, the transmission characteristic S(2,1) of the first band B01 can be lowered (comparing FIGS. 6 and 7). However, increasing the number of resonant elements 50 increases the reflection characteristic S(1,1) in the second band B02.

For example, in the reference example in which the impedance of the intermediate portion 23 is constant, regarding the reflected waves of the frequency of the first band B01, the reflected waves from each of the two adjacent resonant elements 50 are combined with a phase difference of 180 degrees. On the other hand, regarding the reflected waves of the frequency of the second band B02, which is two times the frequency of the first band B01, the reflected waves from each of the two adjacent resonant elements 50 are combined with a phase difference of 360 degrees. In other words, the reflected waves of the frequency of the first band B01 act to cancel each other out and are attenuated. The reflected waves of the frequency of the second band B02 are accumulated and are not attenuated. This also occurs when the SIR structure is applied to the resonant elements 50.

Thus, in the reference example, the configuration of the plurality of resonant elements 50 is devised. In the reference example, if the number of plurality of resonant elements 50 is increased in an attempt to improve the attenuation characteristics in the first band B01, the characteristics in the second band B02 deteriorate. In the reference example, the reflection characteristics near the second harmonic wave deteriorate when plurality of stages are added.

In contrast, in the embodiment, for example, while maintaining high attenuation characteristics in the first band B01, high attenuation characteristics are also obtained in the second band B02. According to the embodiment, a filter circuit capable of improving characteristics can be provided. In the embodiment, for example, it is considered that the reflected waves from the plurality of resonant elements 50 are attenuated by the discontinuous structure of the characteristic impedance (or width) provided in the intermediate portion 23.

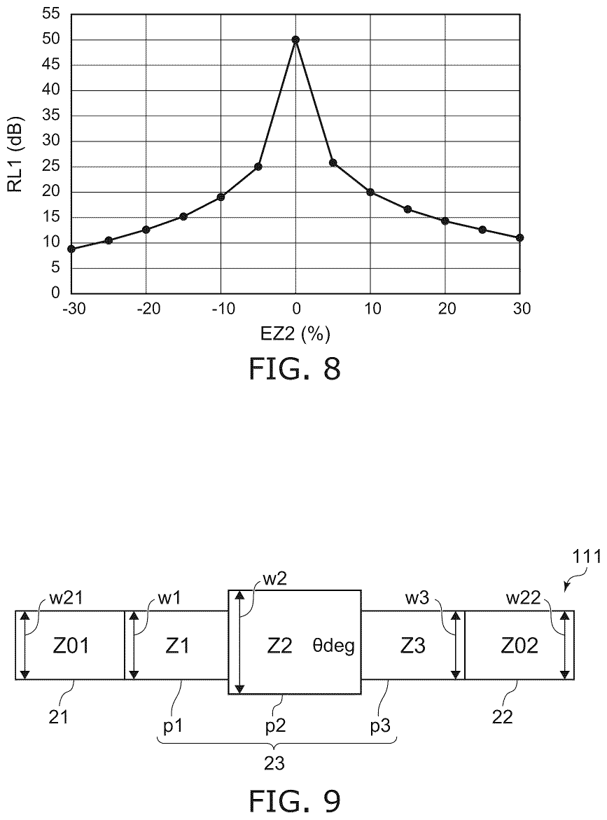

FIG. 8 is a graph illustrating the characteristics of the filter circuit according to the first embodiment.

FIG. 8 illustrates a result of a simulation of the change in characteristics when the second characteristic impedance Z2 of the second portion p2 deviates from the desired value. The horizontal axis of FIG. 8 is the deviation EZ2, and the vertical axis is the return loss RL1. As shown in FIG. 8, when the absolute value of the deviation EZ2 (error) is 15% or less, the return loss RL1 is 15 dB or more. In this embodiment, the error in the “electrical length” may be approximately 15% or less.

FIG. 9 is a schematic diagram illustrating a filter circuit according to the first embodiment.

As shown in FIG. 9, in a filter circuit 111 according to the embodiment, the second line width w2 of the second portion p2 is wider than the first line width w1 of the first portion p1. The second line width w2 is wider than the third line width w3 of the third portion p3. In this case as well, a discontinuous width change is provided. In this example, the second line width w2 is wider than the input portion line width w21. The second line width w2 is wider than the output portion line width w22.

In the filter circuit 111, the second characteristic impedance Z2 of the second portion p2 is lower than the first characteristic impedance Z1 of the first portion p1. The second characteristic impedance Z2 is lower than the third characteristic impedance Z3 of the third portion p3. In this case as well, a discontinuous change in characteristic impedance is provided. In this example, the second characteristic impedance Z2 is lower than the input portion characteristic impedance Z01 of the input portion 21. The second characteristic impedance Z2 is lower than the output portion characteristic impedance Z02 of the output portion 22.

Below, several examples of the configuration of the filter circuit according to the embodiment will be described.

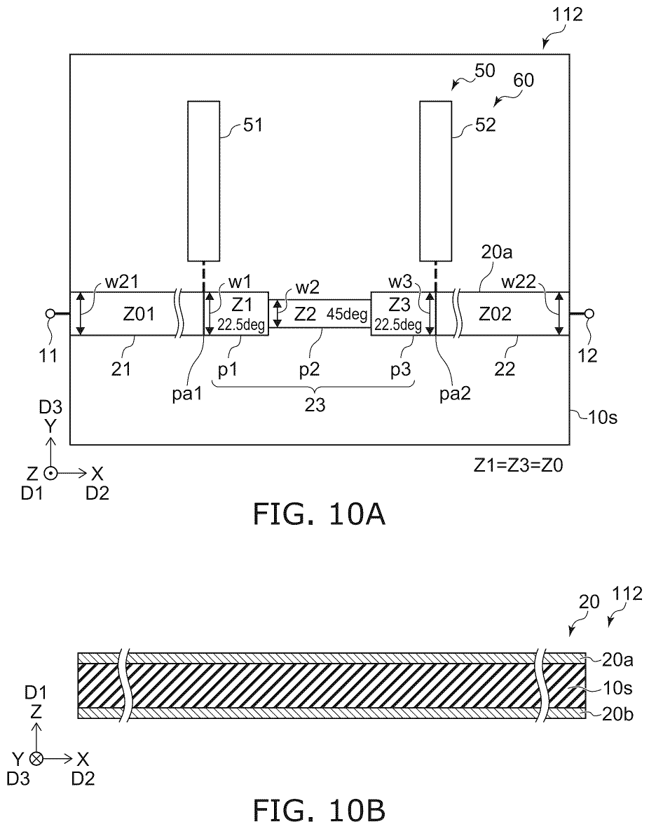

FIGS. 10A and 10B are schematic views illustrating a filter circuit according to the first embodiment.

FIG. 10A is a plan view. FIG. 10B is a cross-sectional view taken along a cross section passing through the transmission line 20 and along the transmission line 20.

As shown in FIGS. 10A and 10B, the filter circuit 112 according to the embodiment includes the base 10s, a first conductive layer 20a, and a second conductive layer 20b. The base 10s is between the second conductive layer 20b and the first conductive layer 20a. The base 10s may be insulating. The transmission line 20 and the plurality of resonant elements 50 may be formed by the first conductive layer 20a. The second conductive layer 20b is, for example, a ground layer.

A first direction D1 from the second conductive layer 20b to the first conductive layer 20a is defined as a Z-axis direction. A direction perpendicular to the Z-axis direction is defined as an X-axis direction. A direction perpendicular to the Z-axis direction and the X-axis direction is defined as a Y-axis direction. The transmission line 20 is, for example, along a second direction D2 crossing the first direction D1. The second direction D2 may be, for example, the X-axis direction. The first conductive layer 20a is along a plane (X-Y plane) including the second direction D2 and the third direction D3. The third direction D3 crosses the plane including the first direction D1 and the second direction D2. The third direction D3 is, for example, the Y-axis direction.

In the filter circuit 112, the plurality of resonant elements 50 have a ½ wavelength microstrip line structure.

The base 10s may include at least one of an inorganic material and an organic material. The base 10s may include at least one of a resin, a ceramic, and a composite material, for example. The resin may include at least one of a polyimide, a liquid crystal polymer, and a fluororesin, for example. The ceramic may include aluminum oxide, etc. The inorganic material may include magnesium oxide, sapphire, silicon, etc. The composite material may include glass cloth, for example. The base 10s may include a material used in flexible substrates.

The first conductive layer 20a and the second conductive layer 20b may include a metal. The metal may include, for example, at least one selected from the group consisting of gold and copper. These conductive layers may include, for example, at least one selected from the group consisting of aluminum, niobium, and tantalum. These conductive layers may include at least one selected from the group consisting of an alloy including aluminum, an alloy including niobium (such as niobium titanium), and an alloy including tantalum. These conductive layers may include a material that exhibits superconducting properties at low temperatures.

In the filter circuit 112, the plurality of resonant elements 50 are coupled with the transmission line 20. The distance between the open ends of the microstrip lines of the plurality of resonant elements 50 and the transmission line 20 is set to be short. This provides capacitive coupling.

The line length of the microstrip line resonator may be set, for example, so that the first resonant frequency f1 of the first resonant element 51 is substantially the same as the second resonant frequency f2 of the second resonant element 52. This increases the amount of attenuation in the first band B01.

In the filter circuit 112, the second characteristic impedance Z2 is, for example, 65 Ω. The second electrical length θ2 is substantially 45 degrees in the first band B01. The first characteristic impedance Z1 and the third characteristic impedance Z3 are 50 Ω. The first electrical length θ1 and the third electrical length θ3 are each substantially 22.5 degrees in the first band B01. The electrical length of the intermediate portion 23 is 90 degrees. The input portion characteristic impedance Z01 and the output portion characteristic impedance Z02 are each 50 Ω.

For example, the relative dielectric constant of the base 10s is 3.4. The thickness of the base 10s is 0.5 mm. The line width at which the characteristic impedance is 50 Ω is 1.1 mm. The line width at which the characteristic impedance is 65 Ω is 0.71 mm.

As one example, in the case of the first band B01 of 1 GHz, the electrical length of the plurality of resonant elements 50 is substantially 180 degrees at 1 GHz. The line lengths of the plurality of resonant elements 50 are set so as to obtain such an electrical length.

For example, when a line width that results in a characteristic impedance of 50 Ω is applied, the line length at which the electrical length at 1 GHz is 180 degrees is 91.8 mm. In the filter circuit 112, it is possible to reduce reflected waves of a specific frequency on the high frequency side of the passband. A filter circuit with good characteristics is obtained.

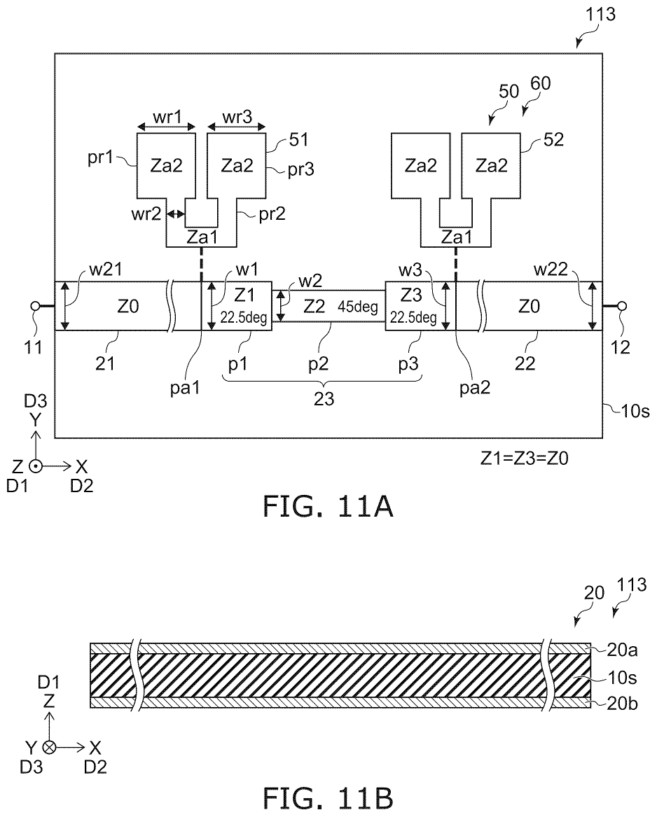

FIGS. 11A and 11B are schematic views illustrating a filter circuit according to the first embodiment.

FIG. 11A is a plan view. FIG. 11B is a cross-sectional view taken along a cross section passing through the transmission line 20 and along the transmission line 20.

As shown in FIG. 11A, in a filter circuit 113 according to the embodiment, the plurality of resonant elements 50 have the SIR structure. The configuration of the filter circuit 113 except for this may be the same as the configuration of the filter circuit 112.

In the filter circuit 113, the width of each of the two end portions of the resonant elements 50 is wider than the width of the portion connecting the two end portions. The distance between the two end portions is close. Parasitic capacitance is effectively obtained by the two end portions. The plurality of resonant elements 50 can be made small. In the SIR structure, the frequency of the high-order resonance can be increased by reducing the width wr2 of the second region pr2 and lowering the impedance ratio Rz. The pass band can be expanded. This provides a wideband filter circuit.

Thus, in the filter circuit 113, at least one of the first resonant element 51 or the second resonant element 52 is a resonator with both ends open. This resonator includes two portions (the first region pr1 and the third region pr3) that form a capacitive element, and a connection part (the second region pr2) that connects these two portions. The characteristic impedance of the connection portion is higher than the characteristic impedance of each of the above two portion. For example, the width wr2 of the second region pr2 is narrower than the width wr1 of the first region pr1. The width wr2 of the second region pr2 is narrower than the width wr3 of the third region pr3.

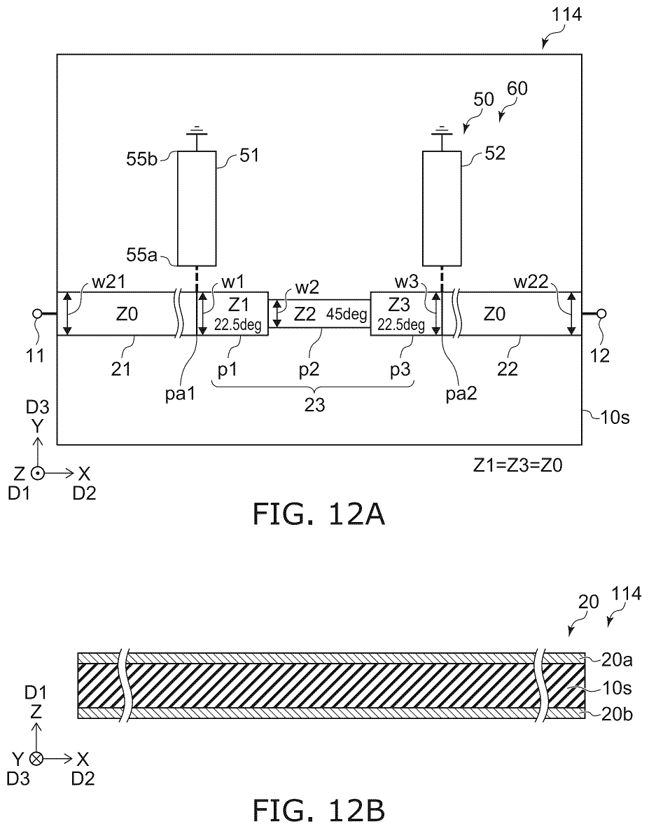

FIGS. 12A and 12B are schematic views illustrating a filter circuit according to the first embodiment.

FIG. 12A is a plan view. FIG. 12B is a cross-sectional view taken along a cross section passing through the transmission line 20 and along the transmission line 20.

As shown in FIG. 12A, in a filter circuit 114 according to the embodiment, the plurality of resonant elements 50 have a line structure. The configuration of the filter circuit 114 except for this may be the same as the configuration of the filter circuit 112.

In the filter circuit 114, at least one of the first resonant element 51 or the second resonant element 52 includes an end 55a being open and another end 55b being grounded. The end 55a is coupled with the transmission line 20.

In the filter circuit 114, a ¼-wavelength resonance can be obtained. The length of the line can be shortened. Miniaturization becomes easier. For example, the frequency offset between the fundamental resonance frequency and the higher-order resonance frequencies can be increased.

The other end 55b may be electrically connected to the second conductive layer 20b, for example, by a conductive member that penetrates the base 10s.

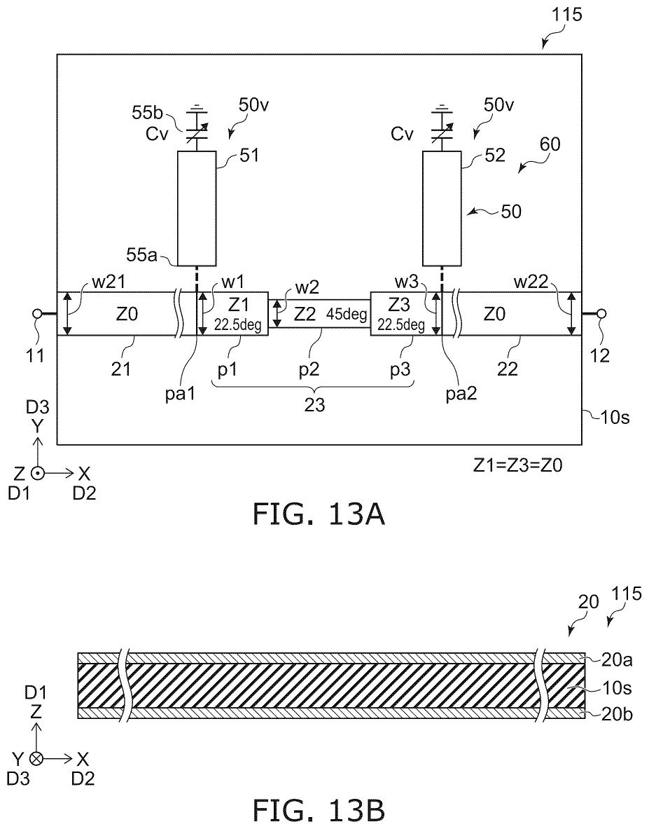

FIGS. 13A and 13B are schematic views illustrating a filter circuit according to the first embodiment.

FIG. 13A is a plan view. FIG. 13B is a cross-sectional view taken along a cross section passing through the transmission line 20 and along the transmission line 20.

As shown in FIG. 13A, in a filter circuit 115 according to the embodiment, the plurality of resonant elements 50 include a variable capacitance Cv. The configuration of filter circuit 115 except for this may be the same as the configuration of filter circuit 112.

In the filter circuit 115, at least one of the first resonant element 51 or the second resonant element 52 includes a frequency variable resonator 50v. The frequency variable resonator 50v includes an end 55a being open, another end 55b being grounded, and a variable capacitance Cv being couplable to the end 55a and the other end 55b. For example, the capacitance can be controlled by controlling a control signal (control voltage) to the variable capacitance Cv. The resonant frequency of the plurality of resonant elements 50 can be changed.

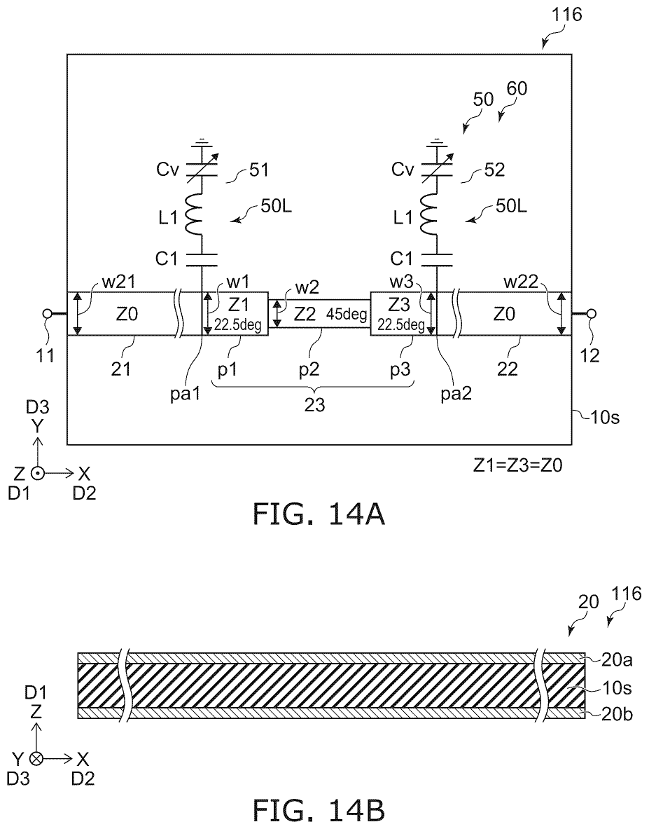

FIGS. 14A and 14B are schematic views illustrating a filter circuit according to the first embodiment.

FIG. 14A is a plan view. FIG. 14B is a cross-sectional view taken along a cross section passing through the transmission line 20 and along the transmission line 20.

As shown in FIG. 14A, in a filter circuit 116 according to the embodiment, the plurality of resonant elements 50 include an LC resonator 50L. The configuration of filter circuit 116 except for this may be the same as the configuration of filter circuit 112.

In the filter circuit 116, at least one of the first resonant element 51 or the second resonant element 52 includes an LC resonator 50L. The LC resonator 50L includes an inductor L1 and a lumped-element C1, such as a chip capacitor, which is configured to be coupled with the inductor L1. The LC resonator 50L may include a variable capacitance Cv. The resonant frequency can be controlled. In the filter circuit 116, the LC resonator 50L may be a parallel resonant circuit.

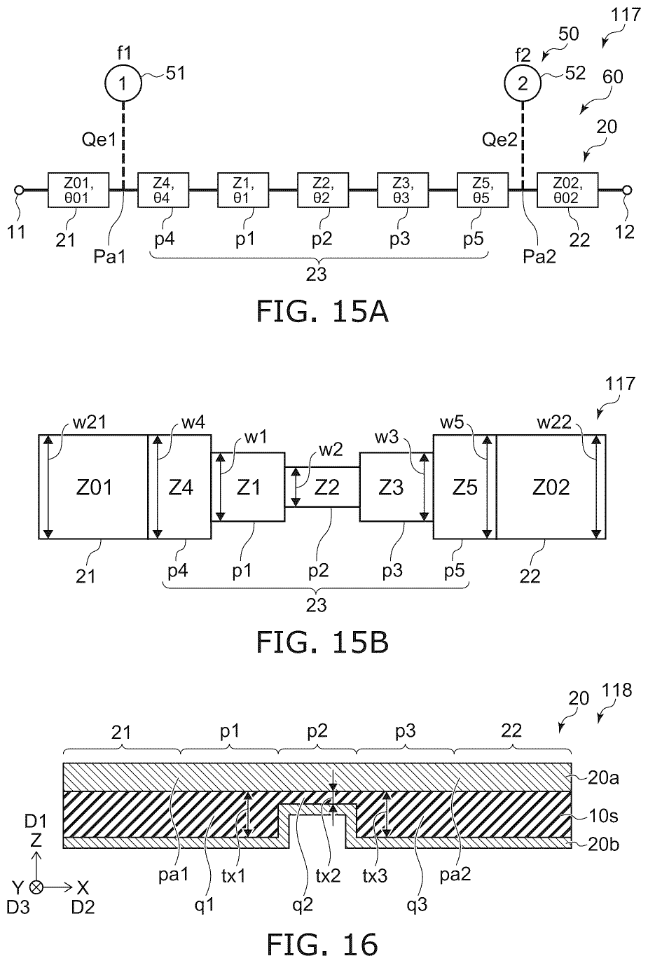

FIGS. 15A and 15B are schematic diagrams illustrating a filter circuit according to the first embodiment.

As shown in FIG. 15A, in a filter circuit 117 according to the embodiment, the intermediate portion 23 includes a fourth portion p4 and a fifth portion p5. The filter circuit 117 may have a configuration similar to the various filter circuits described above (such as the filter circuit 110).

In the filter circuit 117, the intermediate portion 23 includes the fourth portion p4 and the fifth portion p5 in addition to the first portion p1, the second portion p2, and the third portion p3. The fourth portion p4 is between the input portion 21 and the first portion p1. The fifth portion p5 is between the third portion p3 and the output portion 22.

For example, the fourth characteristic impedance Z4 of the fourth portion p4 is different from the first characteristic impedance Z1. The fifth characteristic impedance Z5 of the fifth portion p5 is different from the third characteristic impedance Z3. In the filter circuit 117, a discontinuous change in the characteristic impedance is provided between the fourth portion p4 and the first portion p1. A discontinuous change in the characteristic impedance is provided between the third portion p3 and the fifth portion p5. These discontinuous changes result in reflected waves. The reflected waves are effectively utilized.

As shown in FIG. 15B, a fourth line width w4 of the fourth portion p4 is different from the first line width w1. A fifth line width w5 of the fifth portion p5 is different from the third line width w3.

In this example, the fourth characteristic impedance Z4 is lower than the first characteristic impedance Z1. The fifth characteristic impedance Z5 of the fifth portion p5 is lower than the third characteristic impedance Z3. The fourth line width w4 is wider than the first line width w1. The fifth line width w5 is wider than the third line width w3. These relative relationships may be reversed.

A sum of the fourth electrical length θ4 of the fourth portion p4, the first electrical length θ1 of the first portion p1, the second electrical length θ2 of the second portion p2, the third electrical length θ3 of the third portion p3, and the fifth electrical length θ5 of the fifth portion p5 may be, for example, 90×(2n+1) degrees. The sum electrical length may be substantially 90 degrees.

FIG. 16 is a schematic cross-sectional view illustrating a filter circuit according to the first embodiment.

As shown in FIG. 16, in a filter circuit 118 according to the embodiment, the thickness of the base 10s is not constant. A difference in thickness may be provided to create a difference in characteristic impedance. For example, the base 10s includes a portion q1 overlapping the first portion p1 in the first direction D1, a portion q2 overlapping the second portion p2 in the first direction D1, and a portion q3 overlapping the third portion p3 in the first direction D1. The thickness tx2 of the portion q2 is different from the thickness tx1 of the portion q1. The thickness tx2 is different from the thickness tx3 of the portion q3.

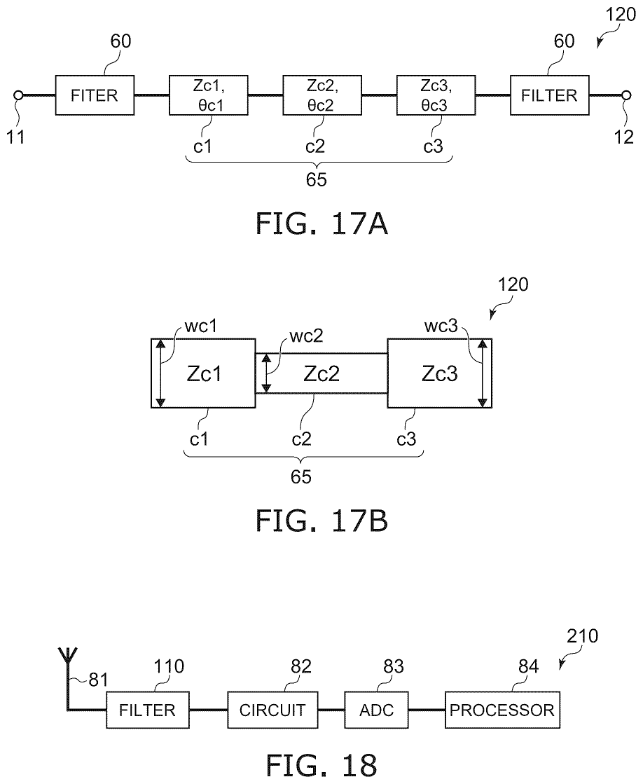

FIGS. 17A and 17B are schematic diagrams illustrating a filter circuit according to the first embodiment.

As shown in FIG. 17A, a filter circuit 120 according to the embodiment includes a plurality of filter elements 60. The configuration of the filter circuit 120 except for this may be the same as the configuration of the filter already described (e.g., filter circuit 110, etc.).

The plurality of filter elements 60 may be configured to be coupled in series. The first band B01 of one of the plurality of filter elements 60 is different from the first band B01 of another one of the plurality of filter elements 60. By coupling plurality of filter elements 60 having different attenuation bands, a wideband filter can be provided.

As shown in FIG. 17A, the filter circuit 120 may further include a coupling transmission line 65. The coupling transmission line 65 is provided between one of the plurality of filter elements 60 and another one of the plurality of filter elements 60.

The coupling transmission line 65 may include, for example, a first coupling portion c1, a second coupling portion c2, and a third coupling portion c3. The first coupling portion c1 is configured to be coupled with one of the plurality of filter elements 60. The third coupling portion c3 is configured to be coupled with another one of the plurality of filter elements 60. The second coupling portion c2 is between the first coupling portion c1 and the third coupling portion c3.

A second coupling portion characteristic impedance Zc2 of the second coupling portion c2 may be different from a first coupling portion characteristic impedance Zc1 of the first coupling portion c1. The second coupling portion characteristic impedance Zc2 may be different from a third coupling portion characteristic impedance Zc3 of the third coupling portion c3.

As shown in FIG. 17B, for example, a second coupling portion width wc2 of the second coupling portion c2 is different from a first coupling portion width wc1 of the first coupling portion c1. The second coupling portion width wc2 is different from a third coupling portion width wc3 of the third coupling portion c3.

In the embodiment, the intermediate portion 23 may satisfy at least one of the first condition or the second condition. In the first condition, the second coupling portion width wc2 is different from the first coupling portion width wc1, and the second coupling portion width wc2 is different from the third coupling portion width wc3. In the second condition, the second coupling portion characteristic impedance Zc2 is different from the first coupling portion characteristic impedance Zc1, and the second coupling portion characteristic impedance Zc2 is different from the third coupling portion characteristic impedance Zc3.

In the coupling transmission line 65, a discontinuous change in characteristic impedance is provided. The reflected wave obtained by the discontinuous change may be used to improve the attenuation characteristics. For example, a plurality of filter elements 60 having the first bands B01 being different are efficiently coupled.

A sum of the first coupling portion electrical length θc1 of the first coupling portion c1, the second coupling portion electrical length θc2 of the second coupling portion c2, and the third coupling portion electrical length θc3 of the third coupling portion c3 may be substantially 90 degrees (for example, not less than 85 degrees and not more than 95 degrees) in the frequency band in which the reflected wave is reduced.

### Second Embodiment

FIG. 18 is a schematic diagram illustrating a communication device according to a second embodiment.

As shown in FIG. 18, a communication device 210 according to the embodiment includes a filter circuit (such as the filter circuit 110) according to the first embodiment. In this example, the communication device 210 includes an antenna 81, a transmitting/receiving circuit 82, a converter 83, and a processor 84.

In a case where the communication device 210 is a receiving device, a communication signal received by the antenna 81 is supplied to the filter circuit 110. In the filter circuit 110, signals of the target frequency in the first band B01 are attenuated, and signals in other pass bands pass. The passed signal may be subjected to processing such as detection and amplification by the transmitting/receiving circuit 82. The output of the transmitting/receiving circuit 82 is subjected to, for example, AD conversion in the converter 83. The converted signal is processed in the processor 84, and the desired signal (or information) is obtained.

In a case where the communication device 210 is a transmitting device, a communication signal from the transmitting/receiving circuit 82 is supplied to the antenna 81 via the filter circuit 110. In the filter circuit 110, signals of the target frequency in the first band B01 are attenuated, and signals of other pass bands pass.

Thus, the communication device 210 according to the embodiment may include a filter circuit (e.g., the filter circuit 110, etc.) according to the first embodiment, and the transmitting/receiving circuit 82. The transmitting/receiving circuit 82 is configured to receive or transmit a communication signal via the filter circuit (e.g., the filter circuit 110, etc.). The filter circuit (e.g., the filter circuit 110, etc.) is configured to attenuate the frequency components of the first band of the communication signal.

The filter circuit according to the embodiment may include various circuit structures. The filter circuit according to the embodiment may include, for example, a coplanar structure, a stripline, a coaxial, or a waveguide circuit structure.

In the specification, “electrical length” may include not only a strict length but also, for example, variations in the manufacturing process. The “electrical length” may be substantially the exemplified value.

The embodiment may include the following Technical proposals:

### (Technical Proposal 1)

A filter circuit, comprising:
a first terminal;
a second terminal; and
a filter element,
the filter element including:
   a transmission line configured to be coupled with the first terminal and the second terminal, and
   a first resonant element and a second resonant element configured to be coupled with the transmission line,
the first resonant element and the second resonant element being configured to resonate at a frequency in a first band being of an object,
the transmission line including:
   an input portion configured to be coupled with the first terminal,
   an output portion configured to be coupled with the second terminal, and
   an intermediate portion between the input portion and output portion,
the first resonant element being configured to be coupled to a first position between the input portion and the intermediate portion,
the second resonant element being configured to be coupled to a second position between the intermediate portion and the output portion,
the intermediate portion including:
   a first portion,
   a second portion between the first portion and the output portion, and
   a third portion between the second portion and the output portion,
a second line width of the second portion being different from a first line width of the first portion, and
the second line width being different from a third line width of the third portion.

### (Technical Proposal 2)

The filter circuit according to Technical proposal 1, wherein
a second characteristic impedance of the second portion is different from a first characteristic impedance of the first portion, and
the second characteristic impedance is different from a third characteristic impedance of the third portion.

### (Technical Proposal 3)

The filter circuit according to Technical proposal 1, wherein
a second characteristic impedance of the second portion is higher than a first characteristic impedance of the first portion, and
the second characteristic impedance is higher than a third characteristic impedance of the third portion.

### (Technical Proposal 4)

The filter circuit according to Technical proposal 2 or 3, wherein
the second characteristic impedance is higher than an input portion characteristic impedance of the input portion, and
the second characteristic impedance is higher than an output portion characteristic impedance of the output portion.

### (Technical Proposal 5)

A filter circuit, comprising:
a first terminal;
a second terminal; and
a filter element,
the filter element including:
   a transmission line configured to be coupled with the first terminal and the second terminal, and
   a first resonant element and a second resonant element configured to be coupled with the transmission line,
the first resonant element and the second resonant element being configured to resonate at a frequency in a first band being of an object,
the transmission line including:
   an input portion configured to be coupled with the first terminal;
   an output portion configured to be coupled with the second termina; and,
   an intermediate portion between the input portion and the output portion,
the first resonant element being configured to be coupled to a first position between the input portion and the intermediate portion,
the second resonant element configured to be coupled to a second position between the intermediate portion and the output portion,
the intermediate portion including:
   a first portion;
   a second portion between the first portion and the output portion; and
   a third portion between the second portion and the output portion,
a second characteristic impedance of the second portion being different from a first characteristic impedance of the first portion, and
the second characteristic impedance being different from a third characteristic impedance of the third portion.

### (Technical Proposal 6)

The filter circuit according to any one of Technical proposals 2-5, wherein
a ratio of an absolute value of a difference between the second characteristic impedance and the first characteristic impedance to the first characteristic impedance is 0.01 or more.

### (Technical Proposal 7)

The filter circuit according to any one of technical proposals 1-4, wherein
a ratio of the absolute value of a difference between the second line width and the first line width to the first line width is 0.01 or more.

### (Technical Proposal 8)

The filter circuit according to any one of Technical proposals 1-4, wherein
the second line width is narrower than the first line width, and
the second line width is narrower than the third line width.

### (Technical Proposal 9)

The filter circuit according to any one of Technical proposals 1-4, wherein
the second line width is narrower than an input portion line width of the input portion, and
the second line width is narrower than an output portion line width of the output portion.

### (Technical Proposal 10)

The filter circuit according to any one of Technical proposals 1-9, wherein
a second electrical length of the second portion is not less than 40 degrees and not more than 50 degrees at a frequency of the first band.

### (Technical Proposal 11)

The filter circuit according to any one of Technical proposals 1-10, wherein
an intermediate portion electrical length of the intermediate portion is not less than 85 degrees and not more than 95 degrees at a frequency between a fundamental frequency of a fundamental resonance of the first resonant element and a secondary resonant frequency of a secondary resonance of the first resonant element.

### (Technical Proposal 12)

The filter circuit according to any one of Technical proposals 2-6, wherein
the intermediate portion further includes:
   a fourth portion between the input portion and the first portion, and
   a fifth portion between the third portion and the output portion,
a fourth characteristic impedance of the fourth portion is different from the first characteristic impedance, and
a fifth characteristic impedance of the fifth portion is different from the third characteristic impedance.

### (Technical Proposal 13)

The filter circuit according to any one of Technical proposals 1-4, wherein
the intermediate portion further includes:
   a fourth portion between the input portion and the first portion, and
   a fifth portion between the third portion and the output portion,
a fourth line width of the fourth portion is different from the first line width, and
a fifth line width of the fifth portion is different from the third line width.

### (Technical Proposal 14)

The filter circuit according to any one of Technical proposals 1-4, comprising:
a plurality of the filter elements,
the plurality of filter elements being configured to be coupled in series,
the first band in one of the plurality of the filter elements being different from the first band in another one of the plurality of the filter elements.

### (Technical Proposal 15)

The filter circuit according to Technical proposal 14, further comprising:
a coupling transmission line,
the coupling transmission line being between the one of the plurality of filter elements and the other one of the plurality of filter elements,
the coupling transmission line including:
   a first coupling portion configured to be coupled with the one of the plurality of filter elements;
   a third coupling portion configured to be coupled with the other one of the plurality of filter elements; and
   a second coupling portion between the first coupling portion and the third coupling portion,
the intermediate portion satisfies at least one of a first condition or a second condition,
in the first condition, a second coupling portion width of the second coupling portion being different from a first coupling portion width of the first coupling portion, and the second coupling portion width being different from a third coupling portion width of the third coupling portion, and
in the second condition, a second coupling portion characteristic impedance of the second coupling portion being different from a first coupling portion characteristic impedance of the first coupling portion, and the second coupling portion characteristic impedance being different from a third coupling portion characteristic impedance of the third coupling portion.

### (Technical Proposal 16)

The filter circuit according to any one of Technical proposals 1-15, wherein
at least one of the first resonant element or the second resonant element is a resonator with both ends open,
the resonator includes two portions forming a capacitive element and a connection portion connecting the two portions, and
a characteristic impedance of the connection portion is higher than a characteristic impedance of each of the two portions.

### (Technical Proposal 17)

The filter circuit according to any one of Technical proposals 1-15, wherein
at least one of the first resonant element or the second resonant element includes:
one end being open; and
another end being grounded.

### (Technical Proposal 18)

The filter circuit according to any one of Technical proposals 1-16, wherein
at least one of the first resonant element or the second resonant element includes a frequency-variable resonator,
the frequency-variable resonator includes:
one end being open;
another end being grounded; and
a variable capacitance being configured to be coupled with the one end and the other end.

### (Technical Proposal 19)

The filter circuit according to any one of Technical proposals 1-15, wherein
at least one of the first resonant element or the second resonant element includes an LC resonator,
the LC resonator includes:
   an inductor; and
   a lumped element configured to be coupled with the inductor.

### (Technical Proposal 20)

A communication device comprising:
the filter circuit according to any one of Technical proposals 1 to 19; and
a transmitting/receiving circuit configured to receive or transmit a communication signal via the filter circuit,
the filter circuit being configured to attenuate a frequency component of the first band of the communication signal.

According to the embodiment, a filter circuit and a communication device are provided that can improve characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the filter circuits such as transmission lines, resonant elements, conductive layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all filter circuits and all communication devices practicable by an appropriate design modification by one skilled in the art based on the filter circuits and the communication devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A filter circuit, comprising:
a first terminal;
a second terminal; and
a filter element,
the filter element including:
a transmission line configured to be coupled with the first terminal and the second terminal, and
a first resonant element and a second resonant element configured to be coupled with the transmission line,
the first resonant element and the second resonant element being configured to resonate at a frequency in a first band being of an object,
the transmission line including:
an input portion configured to be coupled with the first terminal,
an output portion configured to be coupled with the second terminal, and
an intermediate portion between the input portion and output portion,
the first resonant element being configured to be coupled to a first position between the input portion and the intermediate portion,
the second resonant element being configured to be coupled to a second position between the intermediate portion and the output portion,
the intermediate portion including:
a first portion,
a second portion between the first portion and the output portion, and
a third portion between the second portion and the output portion,
a second line width of the second portion being different from a first line width of the first portion, and
the second line width being different from a third line width of the third portion.

2. The filter circuit according to claim 1, wherein
a second characteristic impedance of the second portion is different from a first characteristic impedance of the first portion, and
the second characteristic impedance is different from a third characteristic impedance of the third portion.

3. The filter circuit according to claim 1, wherein
a second characteristic impedance of the second portion is higher than a first characteristic impedance of the first portion, and
the second characteristic impedance is higher than a third characteristic impedance of the third portion.

4. The filter circuit according to claim 2, wherein
the second characteristic impedance is higher than an input portion characteristic impedance of the input portion, and
the second characteristic impedance is higher than an output portion characteristic impedance of the output portion.

5. A filter circuit, comprising:
a first terminal;
a second terminal; and
a filter element,
the filter element including:
a transmission line configured to be coupled with the first terminal and the second terminal, and
a first resonant element and a second resonant element configured to be coupled with the transmission line,
the first resonant element and the second resonant element being configured to resonate at a frequency in a first band being of an object,
the transmission line including:
an input portion configured to be coupled with the first terminal;
an output portion configured to be coupled with the second termina; and,
an intermediate portion between the input portion and the output portion,
the first resonant element being configured to be coupled to a first position between the input portion and the intermediate portion,
the second resonant element configured to be coupled to a second position between the intermediate portion and the output portion,
the intermediate portion including:
a first portion;
a second portion between the first portion and the output portion; and
a third portion between the second portion and the output portion,
a second characteristic impedance of the second portion being different from a first characteristic impedance of the first portion, and
the second characteristic impedance being different from a third characteristic impedance of the third portion.

6. The filter circuit according to claim 2, wherein
a ratio of an absolute value of a difference between the second characteristic impedance and the first characteristic impedance to the first characteristic impedance is 0.01 or more.

7. The filter circuit according to claim 1, wherein
a ratio of the absolute value of a difference between the second line width and the first line width to the first line width is 0.01 or more.

8. The filter circuit according to claim 1, wherein
the second line width is narrower than the first line width, and
the second line width is narrower than the third line width.

9. The filter circuit according to claim 1, wherein
the second line width is narrower than an input portion line width of the input portion, and
the second line width is narrower than an output portion line width of the output portion.

10. The filter circuit according to claim 1, wherein
a second electrical length of the second portion is not less than 40 degrees and not more than 50 degrees at a frequency of the first band.

11. The filter circuit according to claim 1, wherein
an intermediate portion electrical length of the intermediate portion is not less than 85 degrees and not more than 95 degrees at a frequency between a fundamental frequency of a fundamental resonance of the first resonant element and a secondary resonant frequency of a secondary resonance of the first resonant element.

12. The filter circuit according to claim 2, wherein
the intermediate portion further includes:
a fourth portion between the input portion and the first portion, and
a fifth portion between the third portion and the output portion,
a fourth characteristic impedance of the fourth portion is different from the first characteristic impedance, and
a fifth characteristic impedance of the fifth portion is different from the third characteristic impedance.

13. The filter circuit according to claim 1, wherein
the intermediate portion further includes:
a fourth portion between the input portion and the first portion, and
a fifth portion between the third portion and the output portion,
a fourth line width of the fourth portion is different from the first line width, and
a fifth line width of the fifth portion is different from the third line width.

14. The filter circuit according to claim 1, comprising:
a plurality of the filter elements,
the plurality of filter elements being configured to be coupled in series,
the first band in one of the plurality of the filter elements being different from the first band in another one of the plurality of the filter elements.

15. The filter circuit according to claim 14, further comprising:
a coupling transmission line,
the coupling transmission line being between the one of the plurality of filter elements and the other one of the plurality of filter elements,
the coupling transmission line including:
a first coupling portion configured to be coupled with the one of the plurality of filter elements;
a third coupling portion configured to be coupled with the other one of the plurality of filter elements; and
a second coupling portion between the first coupling portion and the third coupling portion,
the intermediate portion satisfies at least one of a first condition or a second condition,
in the first condition, a second coupling portion width of the second coupling portion being different from a first coupling portion width of the first coupling portion, and the second coupling portion width being different from a third coupling portion width of the third coupling portion, and
in the second condition, a second coupling portion characteristic impedance of the second coupling portion being different from a first coupling portion characteristic impedance of the first coupling portion, and the second coupling portion characteristic impedance being different from a third coupling portion characteristic impedance of the third coupling portion.

16. The filter circuit according to claim 1, wherein
at least one of the first resonant element or the second resonant element is a resonator with both ends open,
the resonator includes two portions forming a capacitive element and a connection portion connecting the two portions, and
a characteristic impedance of the connection portion is higher than a characteristic impedance of each of the two portions.

17. The filter circuit according to claim 1, wherein
at least one of the first resonant element or the second resonant element includes:
one end being open; and
another end being grounded.

18. The filter circuit according to claim 1, wherein
at least one of the first resonant element or the second resonant element includes a frequency-variable resonator,
the frequency-variable resonator includes:
one end being open;
another end being grounded; and
a variable capacitance being configured to be coupled with the one end and the other end.

19. The filter circuit according to claim 1, wherein
at least one of the first resonant element or the second resonant element includes an LC resonator,
the LC resonator includes:
an inductor; and
a lumped element configured to be coupled with the inductor.

20. A communication device comprising:
the filter circuit according to claim 1; and
a transmitting/receiving circuit configured to receive or transmit a communication signal via the filter circuit,
the filter circuit being configured to attenuate a frequency component of the first band of the communication signal.
